(19) United States
(12) Patent Application Publication
(10) Pub. No.: US 2005/0284518 A1
(43) Pub. Date: Dec. 29, 2005

(54) Compound solar cell and process for producing the same

(75) Inventors: Akimasa Yamada, Ibaraki (JP); Hitoshi Tampo, Ibaraki (JP); Koji Matsubara, Ibaraki (JP); Shigeru Niki, Ibaraki (JP); Keiichiro Sakurai, Ibaraki (JP); Shogo Ishizuka, Ibaraki (JP); Kakuya Iwata, Ibaraki (JP)

Correspondence Address: MORGAN LEWIS & BOCKIUS LLP, 1111 PENNSYLVANIA AVENUE NW, WASHINGTON, DC, 20004, US

(73) Assignee: National Institute of Advanced Industrial Science and Technology

(21) Appl. No.: 11/159,233

(22) Filed: Jun. 23, 2005

(30) Foreign Application Priority Data
Jun. 24, 2004 (JP) P. 2004-185937

(51) Int. Cl. H01L 31/00

(52) U.S. Cl. 136/262; 136/265; 438/95

(57) ABSTRACT

A solar cell which comprises a back metal electrode and a light-absorbing layer comprising a p-type CIGS semiconductor on a substrate in this order, wherein the solar cell further comprises a p-type or low carrier concentration n-type semiconductor layer comprising ZnO between the light-absorbing layer and the back metal electrode, and a process for producing the solar cell.

### BACKGROUND OF THE INVENTION

1. Field of the Invention

The present invention relates to a CIGS compound solar cell and a process for producing the same.

2. Brief Description of the Background Art

A CIGS compound solar cell is a solar cell fundamentally comprising p-type Cu(In₁₋ₓGaₓ)Se₂ (a mix crystal synthesized from copper indium diselenide and copper gallium diselenide in the ratio of (1−x): x) as a light-absorbing layer and ZnO (zinc oxide) as a window layer. In a solar cell, since a light-absorbing layer plays the most important role for converting light energy into electron/positive hole pairs, the Cu(In₁₋ₓGaₓ)Se₂ solar cell is called a CIGS solar cell named from the capital letters of the elements forming the material (Cu, In, Ga, and Se). The usefulness of the CIGS solar cell has been already well known and its sale has started.

A cross section of a conventional CIGS solar cell structure is illustratively shown in FIG. 1. The basic constitution of the solar cell is obtainable by sequentially laminating a back electrode layer, a light-absorbing layer, a buffer layer, a window layer, a transparent electrode layer, and an antireflective layer on a substrate. A positive electrode terminal and a negative electrode terminal for bringing out a photoelectric conversion current are formed on the back electrode layer and the transparent electrode layer.

Typical material and thickness of each thin film are as follows: the substrate; a glass having a thickness of several mm, the back electrode layer; Mo of about 1 μm, the light-absorbing layer; p-type CIGS having a thickness of about 2 μm, the buffer layer; CdS having a thickness of 50 to 100 nm, the window layer; low carrier concentration n-type ZnO of about 100 nm, the transparent electrode layer; ZnO having a thickness of slightly less than 1 μm, which is formed as a high carrier concentration n-type by adding an element of the Group III, and the antireflective layer; MgF₂ having a thickness of several tens nm. The transparent electrode layer is commonly a degenerated n-type semiconductor obtained by adding an element of Group III (Al, Ga, B, or the like) to ZnO in a high concentration. As the back electrode, it has been known that Au, Ni, and the like are suitable but the material currently used is Mo owing to mechanical strength and economical reasons (Basis and Application of Thin-Film Solar Cell, Chapter 6, edited and written by Makoto Konagai, published by Ohmsha, Ltd. (2001); R. J. Matson, O. Jamjoum, A. D. Buonaquisti, P. E. Russell, L. L. Kazmerski, P. Sheldon and R. K. Aqhrenkiel, Solar Cells, 11, 301 (1984))

Even though conversion efficiency realized in the CIGS solar cell is improved, it is considerably lower than the value theoretically expected. The reason of the low efficiency is considered to be insufficient junction between the window layer and the light-absorbing layer containing the buffer layer and the junction part has been selectively researched and developed.

However, the fact that the difference from the theoretical value is still large even when the efficiency has reached a ceiling and thus the junction part is considered to be almost sufficiently optimized indicates that there is another factor to be solved other than the part.

The performance of a solar cell is evaluated by an open circuit voltage (V_{oc}), a short circuit current, a curve factor, and the conversion efficiency obtained by dividing a product of the three values by a standard incidence power density. Among these, one having the smallest ratio of the value currently achieved to the value theoretically expected is V_{oc}. The magnitude of V_{oc} depends on the width of a forbidden gap (Eg), i.e., x of Cu(In₁₋ₓGaₓ)Se₂. For example, against Eg=1.16 eV, V_{oc} is currently about 0.68 V but, when it reaches the theoretically expected value of 0.84, the conversion efficiency proportional to V_{oc} remarkably increases from 19% to 23%.

The junction part between the window layer and the light-absorbing layer containing the buffer layer has been well studied and it is confirmed that its band mismatch is not so large. Therefore, as the reason why the open circuit voltage is low, band mismatch in the contact between the light-absorbing layer and the back electrode is suspected. As materials for the back electrode, various metals have been tested and Mo is recognized to be suitable among them and hence has been generally used.

Between the CIGS light-absorbing layer and the Mo back electrode, a naturally formed MoSe₂ layer is observed. The substance is a semiconductor and it is reported that band gap energy (Eg₂) thereof is 1.15 eV and electron affinity (χ₂) thereof is 3.8 eV (JP-A-2000-323733).

FIG. 2 shows an energy band lineup in a terminal open state of a CIGS solar cell described so as to be matched to V_{oc}=0.68 V actually obtained. The following values are used: band gap energy of CIGS (Eg₁)=1.16 eV, electron affinity (χ₁)=4.57 eV, and geometrical mean, 4.65 eV, of the value of crystal orientation (110), 4.95 eV, and the value of orientation (112), 4.36 eV, as a work function of Mo (φₘ).

At the interface of CIGS and MoSe₂, since valence band maximum of CIGS (VBM: sum of the electron affinity and the band gap energy) is larger than VBM of MoSe₂, the energy band of CIGS is bent to a larger side (downward in the figure) and the energy band of MoSe₂ is bent to a smaller side (upward in the figure). At the same time, at the interface of MoSe₂ and Mo, since VBM of MoSe₂ is larger than the work function of Mo, the energy band of MoSe₂ is bent to a larger side. As a result, depletion layers are generated on CIGS at the interface of CIGS and MoSe₂ and on MoSe₂ at the interface of MoSe₂ and Mo. Both junctions become Schottky junction to be a barrier of conduction.

The energy difference shown by Eb in FIG. 2 represents the height of the barrier against positive hole. Namely, when Schottky barrier is formed, loss of output voltage occurs by Eb/q, q being a charge elementary quantity.

MoSe₂ is as thin as about 100 nm and effective barrier thickness at the part where the barrier is larger than the work function of Mo further decreases because of the large band bending. Therefore, since tunnel conduction easily occurs, loss in the MoSe₂ layer is almost negligible.

When MoSe₂ is not present, CIGS and Mo come into direct contact and the electron affinity of CIGS and the work function of Mo are close to each other, so that the output of the voltage decreases to less than 0.1 V. Therefore, the formation of MoSe₂ functions to an advantageous direction for a solar cell. However, it is difficult to optionally control the formation of MoSe₂ and MoSe₂ itself is not a suitable substance, so that the Schottky barrier of CIGS at the contact surface with MoSe₂ still remains by any means. Thus, a technology realizing a suitable contact is desired instead of autogenetic MoSe₂.

When a solar cell having a high efficiency close to a theoretical value is intended to obtain, it is a common knowledge that the back electrode should come in ohmic contact with the semiconductor forming a light-absorbing layer. In order to realize the ohmic contact, it is sufficient to use a substance having a work function larger than Fermi energy of the semiconductor as an electrode material. Since an electrode should have a collector function, its electrical resistance is necessarily small and hence a metal is usually used. There are Pt, Pd, Ir and the like as substances satisfying the requirement but they are not easy to use because diffusion during film formation is not negligible in addition to their expensiveness.

### SUMMARY OF THE INVENTION

An object of the present invention is to enhance conversion efficiency of a solar cell by realizing the ohmic contact without using an expensive metal, such as Pt, Pd or Ir, to thereby increase V_{oc} to the utmost extent.

In order to solve the above problem, the present invention has achieved the increase of V_{oc} to the utmost extent by intervening a back buffer layer of a p-type semiconductor containing ZnO as a main component between the light-absorbing layer and the back electrode of a CIGS solar cell.

Namely, the present invention relates to a solar cell which comprises a back metal electrode and a light-absorbing layer comprising a p-type CIGS semiconductor on a substrate in this order,
wherein the solar cell further comprises a p-type or low carrier concentration n-type semiconductor layer comprising ZnO between the light-absorbing layer and the back metal electrode.

Moreover, the present invention relates to a process for producing a solar cell, which comprises:
forming a back metal electrode on a substrate,
forming thereon a ZnO layer by a pulse laser deposition method or a sputtering method using a ZnO target comprising a p-type additive, and
forming a light-absorbing layer of a p-type CIGS semiconductor.

Furthermore, the present invention relates to the above process for producing a solar cell, wherein the ZnO layer is formed by using a ZnO target for pulse laser deposition or sputtering to which one or more compounds selected from the group consisting Of PₘOₙ in which m and n each represents an integer, KNO₃, K₃PO₄, K₄P₂O₇, K₂SO₄, KOH, K₂O, K₂S, K₂Se, NH₄NO₃, and (NH₄)₃PO₄.

Also, the present invention relates to a process for producing a solar cell, which comprises:
forming a back metal electrode on a substrate,
forming thereon a p-type or low carrier concentration n-type ZnO layer by a deposition method accompanied by simultaneous irradiation of a precursor containing nitrogen, phosphorus or potassium, and
forming a light-absorbing layer of a p-type CIGS semiconductor.

In addition, the present invention relates to a process for producing a solar cell, which comprises:
forming a back metal electrode on a substrate,
forming a ZnO layer thereon, followed by thermal treatment to form a p-type or low carrier concentration n-type ZnO layer, and
forming a light-absorbing layer of a p-type CIGS semiconductor.

### BRIEF DESCRIPTION OF THE DRAWINGS

FIG. 1 shows a pattern diagram of cross-section of a conventional CIGS solar cell.

FIG. 2 shows a drawing of energy band of a conventional CIGS solar cell.

FIG. 3 shows a pattern diagram of cross-section of the CIGS solar cell of the present invention.

FIG. 4 shows a drawing of energy band of the CIGS solar cell of the present invention.

FIG. 5 shows a schematic view of a pulse laser deposition apparatus (PLD apparatus).

### DETAILED DESCRIPTION OF THE INVENTION

By providing a p-type or low carrier concentration n-type semiconductor layer containing ZnO as a main component between the light-absorbing layer and the above back metal electrode according to the present invention, loss originated from mismatch in the work function of the back electrode material relative to the material of the light-absorbing layer of the CIGS solar cell can be reduced and thus conversion efficiency can reach near to theoretically maximum conversion efficiency.

Next, modes for carrying out the present invention are described in detail with reference to drawings.

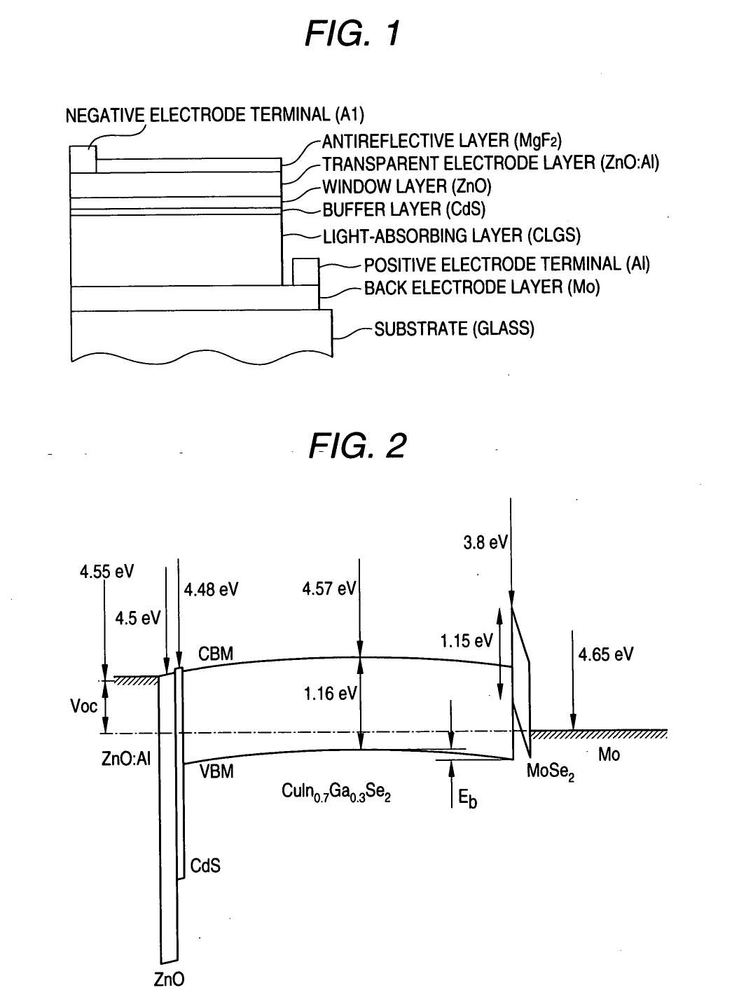

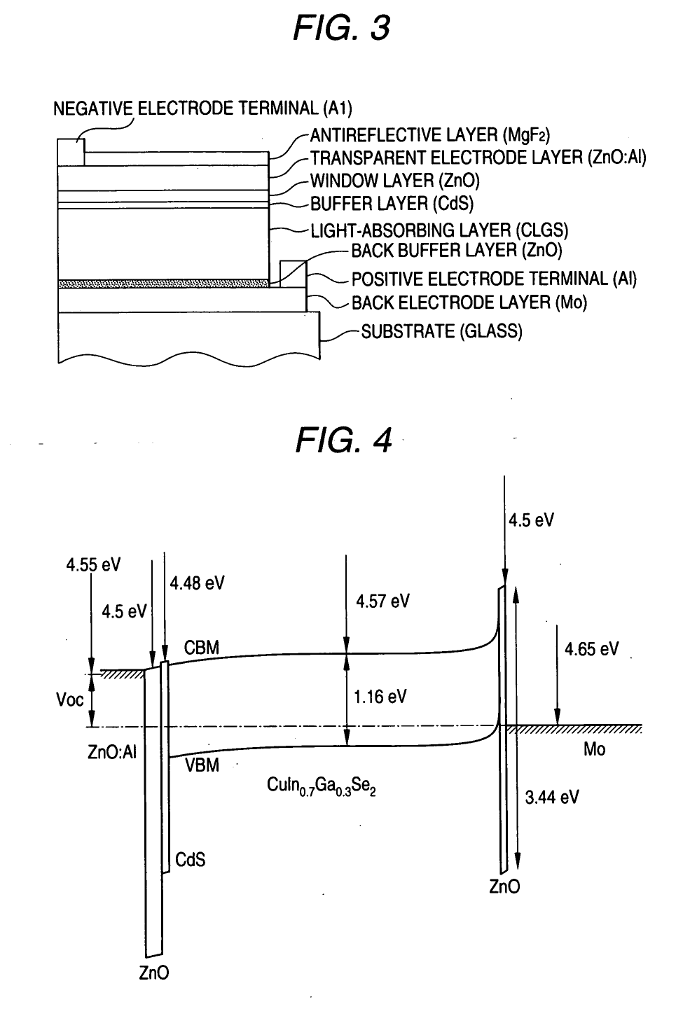

FIG. 3 is a pattern diagram of cross-section illustrating Example of the present invention, which is about the same as that of FIG. 1 but is characterized in that a buffer layer composed of ZnO is provided between the light-absorbing layer and the back electrode.

The reason why ZnO is selected as a material for the back buffer layer is that the substance has a large electron affinity. Namely, ohmic contact is obtained toward p-type CIGS and thus a barrier against the current of positive hole in CIGS disappears.

Incidentally, since ZnO has a large electron affinity, n-type ZnO is easy to form but p-type one is difficult to prepare and ZnO having intrinsic Fermi energy (almost middle point of forbidden band) is not obtained. However, as shown in FIG. 4, since ZnO has a large electron affinity and also a wide forbidden band of 3.4 eV, as a matter of course in the case of p-type one, even in the case of n-type one, when the concentration is low and is close to intrinsic Fermi energy, it is possible to make Fermi energy of ZnO larger than Fermi energy of CIGS. However, in the case of not only n-type one but also p-type one, when Fermi energy of ZnO is apart from valence band maximum (VBM), the VBM becomes a barrier. In this case, the back buffer layer of ZnO should be made thin so as to achieve tunnel junction.

Recently, it has been revealed that p-type ZnO can be realized by adding P (phosphorus). The method comprises obtaining a thin film to which P is added on a substrate by sputtering a target contaminated with P₂O₅. The effect of the addition of P₂O₅ is understood to be that P replaces an O site to become an acceptor and excessive O fills a hole of the 0 site to reduce a donor.

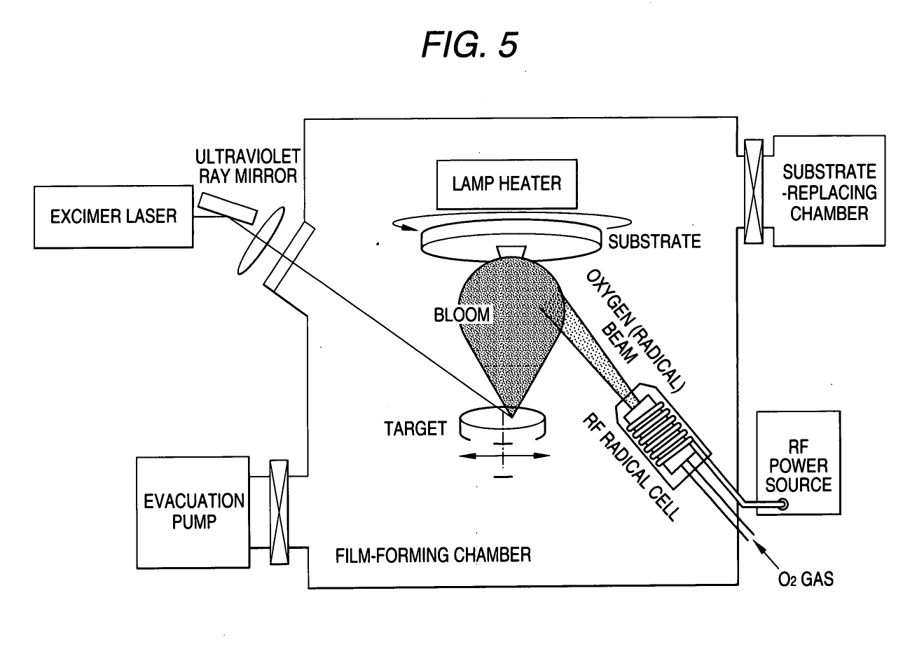

FIG. 5 shows a deposition apparatus of a p-type ZnO film by a pulse laser deposition method (PLD) using a target contaminated with P₂O₅.

The procedure of the film formation is as follows: (1) a growing chamber in which the target and a substrate are included is evacuated to vacuum, (2) the substrate is heated, (3) oxygen is fed under evacuation to maintain a pressure of several tens μTorr, and (4) the target is irradiated with an excimer laser through a window.

The target is one obtained by binding a ZnO powder to which P is added in an amount of about 1 mol %. The temperature of the substrate may be elevated to about 500° C. that is a softening point thereof in the case where the substrate is made of glass but the film formation is also possible at room temperature. Since oxygen can be converted into its radical by feeding a high-frequency electric power to the RF cell, in the case where the result is satisfactory, radical formation is carried out. The laser is a pulse one having a wavelength of 248 nm and an energy density of about 1 mJ/cm². The irradiation with the pulse at a repeating frequency of 20 Hz can result in film formation at a rate of about 0.3 μm/h. Thus, a film having a carrier concentration of 3×10²⁰ cm⁻³ is obtained.

On the other hand, by forming a film of intrinsic conductor ZnO, a film having a low carrier concentration is obtained. In a vacuum chamber evacuated to about 10⁻⁶ Torr, a film having a carrier concentration of 10¹⁶ to 10¹⁷ cm⁻³ is obtained by a method of combining a Zn vapor from a crucible heated to 200 to 300° C. and oxygen fed from the radical cell at a flow rate of about 1 SCCM on the substrate and a film having a carrier concentration of first half of the order of 10¹⁶ cm⁻³ by a method of adding N (nitrogen) simultaneously.

Basically, various compounds comprising an element capable of replacing any sites of ZnO to become an acceptor or of filling a hole of its O site to reduce a donor can be precursors of the additive. In particular, KNO₃, K₃PO₄, K₄P₂O₇, K₂SO₄, KOH, K₂O, K₂S, K₂Se, and PₘOₙ (m, n: an integer) are suitable.

There is a case that thermal treatment is necessary after film formation and, as atmospheric gases at this case, H₂, N₂, O₂, H₂O, H₂S, H₂Se, NₘOₙ, NH₃, and the like are effective. Empirically, an effect appears under N₂ or O₂ atmosphere at 400 to 900° C.

### EXAMPLES

A layer of Mo as a metal to be a collector electrode is attached on the substrate and, before the formation of the CIGS layer, a p-type ZnO or low carrier concentration n-type back buffer layer is deposited. The other processes may be conducted by conventional methods.

As a deposition method of p-type ZnO, a pulse laser deposition method (PLD) and a sputtering method using a target containing a suitable precursor are preferable but other means such as vapor deposition and chemical vapor deposition may be employed.

Those effective for adding to the precursor of the p-type ZnO back buffer layer are PₘOₙ including P₂O₅, KNO₃, K₃PO₄, K₄P₂O₇, K₂SO₄, KOH, K₂O; K₂S, K₂Se, NH₄NO₃, (NH₄)₃PO₄, and the like.

For deposition of n-type ZnO having a low carrier concentration, vapor deposition by simultaneous irradiation of N is most suitable but the other means may be employed.

The precursors of N are N₂, radicals of N₂ and N, NₘOₙ (m, n: an integer), NH₃, and the like.

When thermal treatment is carried out after the deposition of the ZnO back buffer layer, the formation of p-type or low carrier concentration n-type one can be more surely achieved.

As above, preferred modes for carrying out the invention and Examples are described but the invention is not limited thereto. Suitable changes are possible within the range that does not deviate from the gist of the invention.

The usefulness of the CIGS solar cell has been already well known and its sale has started. However, since the improvement of open current voltage is the most important problem to be solved, the present invention is considered to be a key technology in the industrialization of the CIGS thin film solar cell.

While the invention has been described in detail and with reference to specific embodiments thereof, it will be apparent to one skill in the art that various changes and modifications can be made therein without departing from the spirit and scope thereof. All references cited herein are incorporated in their entirety.

This application is based on Japanese patent application No. 2004-185937 filed on Jun. 24, 2004, the entire contents of which are incorporated hereinto by reference.

1. A solar cell which comprises a back metal electrode and a light-absorbing layer comprising a p-type CIGS semiconductor on a substrate in this order, wherein the solar cell further comprises a p-type or low carrier concentration n-type semiconductor layer comprising ZnO between the light-absorbing layer and the back metal electrode.

2. A process for producing a solar cell, which comprises:
forming a back metal electrode on a substrate,
forming thereon a ZnO layer by a pulse laser deposition method or a sputtering method using a ZnO target comprising a p-type additive, and
forming a light-absorbing layer of a p-type CIGS semiconductor.

3. The process according to claim 2, wherein the ZnO layer is formed by using a ZnO target for pulse laser deposition or sputtering to which one or more compounds selected from the group consisting of PₘOₙ in which m and n each represents an integer, KNO₃, K₃PO₄, K₄P₂O₇, K₂SO₄, KOH, K₂O, K₂S, K₂Se, NH₄NO₃, and (NH₄)₃PO₄.

4. A process for producing a solar cell, which comprises:
forming a back metal electrode on a substrate,
forming thereon a p-type or low carrier concentration n-type ZnO layer by a deposition method accompanied by simultaneous irradiation of a precursor containing nitrogen, phosphorus or potassium, and
forming a light-absorbing layer of a p-type CIGS semiconductor.

5. A process for producing a solar cell, which comprises:
forming a back metal electrode on a substrate,
forming a ZnO layer thereon, followed by thermal treatment to form a p-type or low carrier concentration n-type ZnO layer, and
forming a light-absorbing layer of a p-type CIGS semiconductor.
